(19) United States
(12) Patent Application Publication
(10) Pub. No.: US 2015/0048344 A1
(43) Pub. Date: Feb. 19, 2015

(54) ORGANIC LIGHT EMITTING DIODE DISPLAY

(71) Applicant: Samsung Display Co., Ltd., Yongin-City (KR)

(72) Inventor: Byung-Uk HAN, Yongin-City (KR)

(21) Appl. No.: 14/451,673

(22) Filed: Aug. 5, 2014

(30) Foreign Application Priority Data
Aug. 16, 2013 (KR) 10-2013-0097458

(51) Int. Cl. H01L 27/32; H01L 51/52

(52) U.S. Cl. CPC H01L 27/3258; H01L 51/524; H01L 27/3276
USPC 257/40

(57) ABSTRACT

An organic light emitting diode (OLED) display according to an example embodiment of the present invention includes: a substrate and an encapsulation substrate facing each other; a sealing member bonding the substrate and the encapsulation substrate to seal the substrate and the encapsulation substrate; a plurality of pixels positioned on the substrate sealed by the sealing member; a driver positioned on the substrate and electrically connected to the pixels by a plurality of wires; and an insulating layer formed on the substrate and having a recess portion formed at a region corresponding to the sealing member, wherein the wire is positioned within the recess portion.

### CROSS-REFERENCE TO RELATED APPLICATION

This application claims priority to and the benefit of Korean Patent Application No. 10-2013-0097458 filed in the Korean Intellectual Property Office on Aug. 16, 2013, the entire contents of which application are incorporated herein by reference.

### BACKGROUND

1. Field of the Invention

The present invention relates to an organic light emitting diode (OLED) display.

2. Description of Related Technology

An organic light emitting diode display (OLEDD) includes a plurality of OLEDs formed of a hole injection electrode, an organic emission layer, and an electron injection electrode. Each OLED emits light by energy generated when excitons generated as electrons and holes are combined and drop from an excited state to a ground state, and the OLED display displays an image by using the light.

Accordingly, the OLED display has self-luminance characteristics, and unlike a liquid crystal display (LCD), the thickness and weight thereof can be reduced because a separate light source is not required. Further, because the OLED display has high quality characteristics such as low power consumption, high luminance, and high reaction speed, the OLED display is appropriate for use in a mobile electronic device.

The OLED may deteriorate due to internal and external factors. With regard to the internal factors, the organic emissive layer deteriorates under an atmosphere of oxygen as the result of indium tin oxide (ITO) being the electrode material, or under an interfacial reaction between organic layer components of the organic emissive layer. The external factors include external moisture and oxygen, and ultraviolet rays. In particular, as the external oxygen and moisture seriously influence the life span of the OLED, it is very important to package the OLED such that it is sealed from the outside in a vacuum tight manner.

The organic light emitting element is sealed by a sealing member, and the sealing member overlaps and passes through a wire connected to the organic light emitting element.

It is to be understood that this background of the technology section is intended to provide useful background for understanding the disclosed technology and as such, the technology background section may include ideas, concepts or recognitions that were not part of what was known or appreciated by those persons of ordinary skill in the pertinent art prior to corresponding invention dates of subject matter disclosed herein.

### SUMMARY

Accordingly, an organic light emitting diode (OLED) display preventing adhesion of a sealing member from being reduced due to a step of a wire is provided.

An organic light emitting diode (OLED) display includes: a substrate and an encapsulation substrate facing each other; a sealing member bonding the substrate and the encapsulation substrate configured to seal the substrate and the encapsulation substrate; a plurality of pixels positioned on the substrate sealed by the sealing member; a driver positioned on the substrate and electrically connected to at least one of the pixels by a wire; and an insulating layer formed on the substrate and having a recess portion formed at a region corresponding to a position of the sealing member, wherein the wire is positioned within the recess portion.

A depth of the recess portion may be the same as a thickness of the wire.

The wire may have a plurality of openings, and the width of at least one of the plurality of openings in a direction along a length of the wire may be smaller than the thickness of the wire.

The pixel may include a thin film transistor formed on the substrate, and an organic light emitting element connected to the thin film transistor.

The organic light emitting element may include a first electrode, an organic emission layer formed on the first electrode, and a second electrode formed on the organic emission layer, and the first electrode may be connected to a drain electrode of the thin film transistor through a contact hole formed in an interlayer insulating layer.

The insulating layer may be the interlayer insulating layer, and the insulating layer may further include a gate insulating layer positioned between a gate electrode and a semiconductor of the thin film transistor.

The recess portion and the wire may cross the sealing member.

The recess portion may be positioned in a top surface of the insulating layer opposite a surface of the insulating layer facing the substrate.

The sealing portion contacts the top surface of the insulating layer and the wire.

A depth of the recess portion may be less than a thickness of the wire.

The wire may have a plurality of openings, and the sealing member may be positioned in the openings.

### BRIEF DESCRIPTION OF THE DRAWINGS

FIG. 1 is a schematic top plan view of an organic light emitting diode (OLED) display according to an example embodiment.

FIG. 2 is a schematic cross-sectional view of an organic light emitting diode (OLED) display according to an example embodiment.

FIG. 3 is an equivalent circuit of one pixel of an organic light emitting panel according to an example embodiment.

FIG. 4 is a cross-sectional view of one pixel of an organic light emitting diode (OLED) display according to an example embodiment.

FIG. 5 is a top plan view of a portion A of FIG. 1.

FIG. 6A is a cross-sectional view taken along the line VI-VI of FIG. 5.

FIG. 6B is a cross-sectional view showing a relationship between a recess portion and a wire according to another example embodiment.

FIG. 7 is a cross-sectional view taken along the line VII-VII of FIG. 5.

FIG. 8 is a top plan view of a portion A of FIG. 1.

FIG. 9 is a cross-sectional view taken along the line IX-IX of FIG. 8.

FIG. 10 is a cross-sectional view taken along the line X-X of FIG. 8.

### DETAILED DESCRIPTION OF THE EMBODIMENTS

The present disclosure will be described more fully hereinafter with reference to the accompanying drawings, in which example embodiments are shown.

The size and thickness of the configurations are optionally shown in the drawings for the convenience of description and the present invention is not limited to the drawings.

In the drawings, the thickness of layers, films, panels, regions, etc., are exaggerated for clarity. In the drawings, the thicknesses of some layers and areas are exaggerated for convenience of explanation. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Throughout this specification, it is understood that the term “on” and similar terms are used generally and are not necessarily related to a gravitational reference.

Now, an organic light emitting diode (OLED) display will be described with reference to accompanying drawings.

Because a wire connected to the organic light emitting element passes through the sealing member, an upper surface of the sealing member is curved by a step due to the wire thickness. This curve reduces adhesion of the sealing member such that the organic light emitting element is not completely encapsulated and the life-span of the organic light emitting element is influenced.

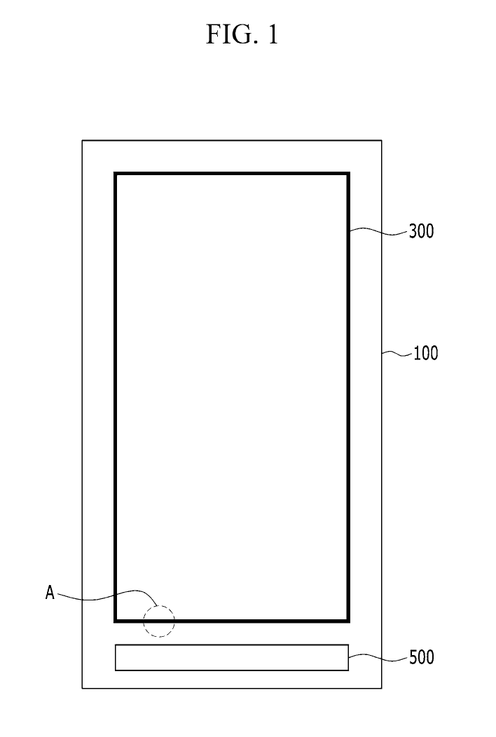

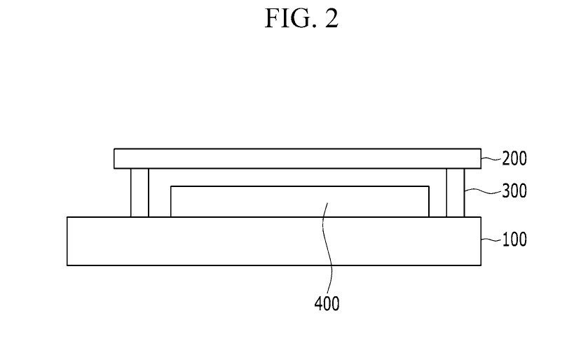

FIG. 1 is a schematic top plan view of an organic light emitting diode (OLED) display according to an example embodiment, and FIG. 2 is a schematic cross-sectional view of an organic light emitting diode (OLED) display according to an example embodiment.

FIG. 1 and as shown in FIG. 2, an organic light emitting diode (OLED) display according to an example embodiment includes a substrate 100 and an encapsulation substrate 200 facing each other, and the substrate 100 and the encapsulation substrate 200 are sealed by a sealant 300.

A pixel unit 400 made of a plurality of pixels respectively including a thin film transistor and an organic light emitting element are formed on the substrate 100. A driver 500 for driving the pixel unit 400 is also formed on the substrate 100.

The sealing member 300 is formed between an edge of the substrate 100 and the encapsulation substrate 200 to enclose the pixel unit 400, thereby forming a closed and sealed space along with the substrate 100 and the encapsulation substrate 200 to protect the pixel unit 400 from external factors.

The encapsulation substrate 200 is formed with a smaller size than the substrate 100 such that the driver 500 formed on the substrate 100 is exposed. The driver 500 includes a driving circuit to drive the pixel unit 400, and the driving circuit may be integrated on the substrate along with the thin film transistor of the pixel or may be mounted on the substrate 100 as an IC chip. In FIG. 1, the driver is formed at one side of the pixel unit, however it may be positioned at both sides of the pixel unit 400.

The driver 500 is electrically connected to the pixel unit 400 by a plurality of signal lines, and each pixel of the pixel unit 400 is controlled by a driving signal transmitted by a plurality of signal lines thereby displaying an image.

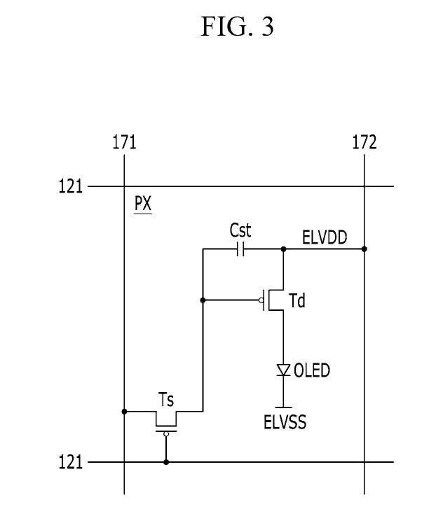

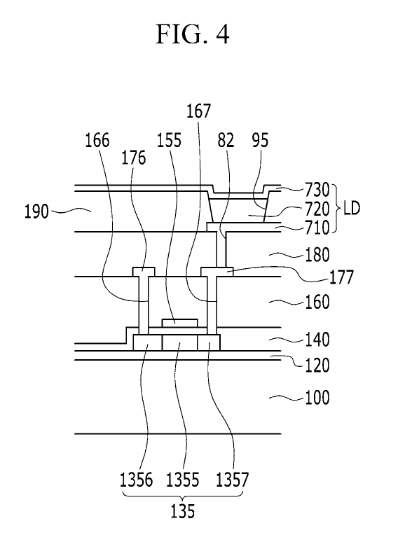

Next, one pixel formed at the pixel unit will be described in detail with reference to FIG. 3 and FIG. 4.

FIG. 3 is an equivalent circuit of one pixel of an organic light emitting panel according to an example embodiment.

Hereafter, a detailed structure of one pixel of an organic light emitting display panel is shown in FIG. 3 and FIG. 4, however embodiments are not limited to the structure shown in FIG. 3 and FIG. 4. The wire and the organic light emitting element are changeable in various manners within the range in which a person of ordinary skill in the art can modify them. For example, a 2Tr-1Cap active matrix (AM) type of display device having two thin film transistors (TFTs) and a capacitor for each pixel is shown for the display device in the drawing, but embodiments are not limited thereto. The display device does not limit the number of thin film transistors, capacitors, and wires. The pixel represents a minimum unit for displaying the image, and the display device uses a plurality of pixels to display the image.

As shown in FIG. 3, the display device includes a plurality of signal lines 121, 171, and 172 and a plurality of pixels (PX) connected thereto and arranged in a matrix form.

The signal lines include a plurality of gate lines 121 for transmitting a gate signal (or a scan signal), a plurality of data lines 171 for transmitting a data signal, and a plurality of driving voltage lines 172 for driving a driving voltage (ELVDD). The gate lines 121 are provided in a row direction and are substantially parallel with each other, and parts of the data lines 171 and the driving voltage lines 172 in a vertical direction are provided in a column direction and are substantially parallel with each other.

The pixel PX includes a switching thin film transistor Ts, a driving thin film transistor Td, a storage capacitor Cst, and an organic light emitting diode (OLED) LD.

The switching thin film transistor Ts includes a control terminal, an input terminal, and an output terminal, and the control terminal is connected to the gate line 121, the input terminal is connected to the data line 171, and the output terminal is connected to the driving thin film transistor Td. The switching thin film transistor Ts responds to the scan signal applied to the gate line 121 to transmit the data signal applied to the data line 171 to the driving thin film transistor Td.

The driving thin film transistor Td includes a control terminal, an input terminal, and an output terminal, and the control terminal is connected to the switching thin film transistor Ts, the input terminal to the driving voltage line 172, and the output terminal to the organic light emitting diode OLED. The driving thin film transistor Td outputs an output current ILD that is variable according to a voltage between the control terminal and the output terminal.

The capacitor Cst is connected between the control terminal of the driving thin film transistor Td and the input terminal. The capacitor Cst charges the data signal applied to the control terminal of the driving thin film transistor Td and maintains it when the switching thin film transistor Ts is turned off.

The organic light emitting diode OLED includes an anode connected to the output terminal of the driving thin film transistor Td and a cathode connected to a common voltage (ELVSS). The organic light emitting diode LD changes intensity and emits light depending on the output current (ILD) of the driving thin film transistor Td to thus display the image.

An inter-layer structure of one pixel of an organic light emitting diode (OLED) display according to an example embodiment will now be described with reference to FIG. 3 and FIG. 4.

FIG. 4 is a cross-sectional view of one pixel of an organic light emitting diode (OLED) display.

The layered configuration of the driving transistor and the switching transistor of FIG. 3 is the same such that a driving transistor connected to the organic light emitting element will be described in FIG. 4.

As shown in FIG. 4, a buffer layer 120 is formed on a substrate 100 of an organic light emitting diode (OLED) display.

The substrate 100 may be, for example, a transparent insulating substrate made of a glass, quartz, ceramic, or polymer material, or the substrate 100 may be a metal substrate made of stainless steel. The polymer material may be, for example, an organic material selected from a group consisting of insulation organic materials, such as polyether sulfone (PES), polyacrylate (PAR), polyetherimide (PEI), polyethylene naphthalate (PEN), polyethylene terephthalate (PET), polyphenylene sulfide (PPS), polyallylate, polyimide, PC, TAC, and cellulose acetate propionate (CAP).

The buffer layer 120 can be formed with a single film of silicon nitride (SiNx) or a plurality of multilayers that are generated by stacking a silicon nitride (SiNx) and a silicon oxide (SiOₓ). The buffer layer 120 prevents permeation of undesired components such as impurity or moisture, and planarizes the surface.

A semiconductor 135 made of polysilicon is formed on the buffer layer 120.

The semiconductor 135 includes a channel region 1355, and a source region 1356 and a drain region 1357 that are formed on respective sides of the channel region 1355. The channel region 1355 of the semiconductor 135 is polysilicon to which an impurity is not doped, that is, an intrinsic semiconductor. The source region 1356 and the drain region 1357 of the semiconductor 135 are polysilicon to which a conductive impurity is doped, that is, an impurity semiconductor.

Inprities that are doped in the source region 1356 and the drain region 1357 may be one of a p-type impurity and an n-type impurity.

A gate insulating layer 140 is formed on the semiconductor 135. The gate insulating layer 140 can be formed, for example, with a single layer of tetraethyl orthosilicate (TEOS), a silicon oxide (SiOₓ), or a silicon nitride (SiNx), or a plurality of multilayers that are formed by stacking a silicon oxide (SiOₓ) and a silicon nitride (SiNx).

A gate electrode 155 is formed on the gate insulating layer 140. The gate electrode 155 is electrically connected to the drain electrode of the switching transistor of FIG. 3.

The gate electrode 155 can be formed, for example, with a single layer or multilayers of a low-resistance material such as Al, Ti, Mo, Cu, Ni, or an alloy thereof, or a high-corrosion material.

A first interlayer insulating layer 160 is formed on the gate electrode 155.

In a like manner of the gate insulating layer 140, the first interlayer insulating layer 160 can be formed, for example, with a single layer of tetraethyl orthosilicate (TEOS), a silicon oxide (SiOₓ), or a silicon nitride (SiNx), or a plurality of multilayers that are formed by stacking a silicon oxide (SiOₓ) and a silicon nitride (SiNx).

The first interlayer insulating layer 160 and the gate insulating layer 140 include a source contact hole 166 for exposing the source region 1356 and a drain contact hole 167 for exposing the drain region 1357.

A source electrode 176 and a drain electrode 177 connected, respectively, to the source region 1356 and the drain region 1357 through the contact holes 166 and 167 are formed on the first interlayer insulating layer 160. The source electrode 176 is connected to a driving voltage line of FIG. 3.

The source electrode 176 and the drain electrode 177 can be formed, for example, with a single layer or multilayers of a low-resistance material such as Al, Ti, Mo, Cu, Ni, or an alloy thereof, or a high-corrosion material. For example, the source electrode 176 and the drain electrode 177 can be triple layers of Ti/Cu/Ti, Ti/Ag/Ti, or Mo/Al/Mo.

A second interlayer insulating layer 180 having a contact hole 82 exposing the drain electrode 177 is formed on the source electrode 176 and the drain electrode 177.

A first electrode 710 connected to the drain electrode 177 through the contact hole 82 is formed on the second interlayer insulating layer 180.

In a like manner of the first interlayer insulating layer, the second interlayer insulating layer 180 can be formed, for example, with a single layer of tetraethyl orthosilicate (TEOS), a silicon oxide (SiOₓ), or a silicon nitride (SiNx), or a plurality of multilayers that are formed by stacking a silicon oxide (SiOₓ) and a silicon nitride (SiNx). The second interlayer insulating layer 180 can also be formed with a low dielectric constant organic material.

The first electrode 710 can be the anode of the organic light emitting diode shown in FIG. 3. In an example embodiment, the second interlayer insulating layer is formed between the first electrode 710 and the drain electrode 177, however the first electrode 710 can be formed on the same layer as the drain electrode 177 and can be integrally formed with the drain electrode 177.

A pixel definition layer 190 is formed on the first electrode 710.

The pixel definition layer 190 has an opening 95 exposing the first electrode 710. The pixel defining layer 190 may be formed by including a resin such as, for example, a polyacrylate or a polyimide, or a silica-based inorganic material.

An organic emission layer 720 is formed in the opening 95 of the pixel defining layer 190.

The organic emission layer 720 includes an emission layer, and may include at least one of a hole transport layer (HTL), a hole-injection layer (HIL), an electron transport layer (ETL), and an electron injection layer (EIL).

In the case where the organic emission layer 720 includes all of them, the hole injection layer (HIL) may be disposed on the first electrode 710 that is the anode, and the hole transport layer (HTL), the emission layer, the electron transport layer (ETL), and the electron injection layer (EIL) may be sequentially laminated thereon.

A second electrode 730 is formed on the pixel definition layer 190 and the organic emission layer 720.

The second electrode 730 becomes a cathode of the organic light emitting element. Accordingly, the first electrode 710, the organic emission layer 720, and the second electrode 730 form an organic light emitting element OLED.

The organic light emitting element OLED can be one of a front display type, a rear display type, and a dual-sided display type according to the direction in which the organic light emitting element OLED emits light.

In the case of the front display type, the first electrode 710 is formed of a reflective layer and the second electrode 730 is formed of a transflective or transmissive layer. In the case of the rear display type, the first electrode 710 is formed of a transflective layer and the second electrode 730 is formed of a reflective layer. In the case of a dual-sided display type, the first electrode 710 and the second electrode 730 are formed of a transparent layer or a transflective layer.

The reflective layer and the semi-transparent layer are made, for example, of at least one of Mg, Ag, Au, Ca, Li, Cr, and Al, or an alloy thereof. The reflective layer and the transflective layer are determined by the thicknesses thereof, and the transflective layer may have a thickness of less than 200 nm. While the transmittance of the reflective layer or transflective layer increases as the thickness thereof decreases, the resistance thereof increases when the layer is excessively thin.

The transmissive layer is made, for example, of indium tin oxide (ITO), indium zinc oxide (IZO), zinc oxide (ZnO), or indium oxide (IN₂O₃).

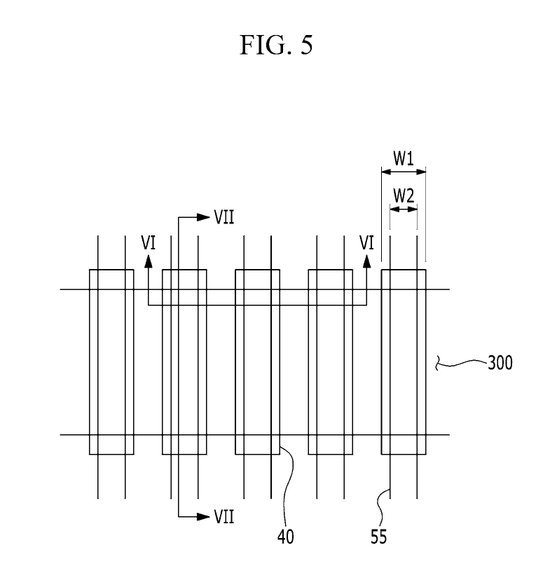

Next, a sealing part of the organic light emitting diode (OLED) display will be described with reference to FIGS. 5 to 10.

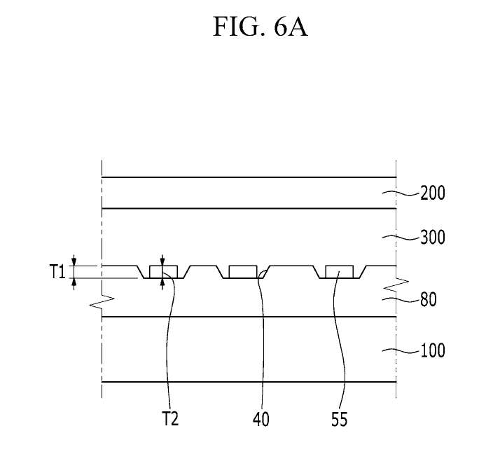

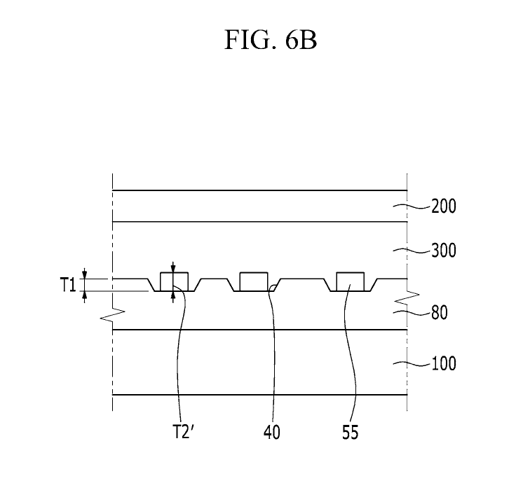

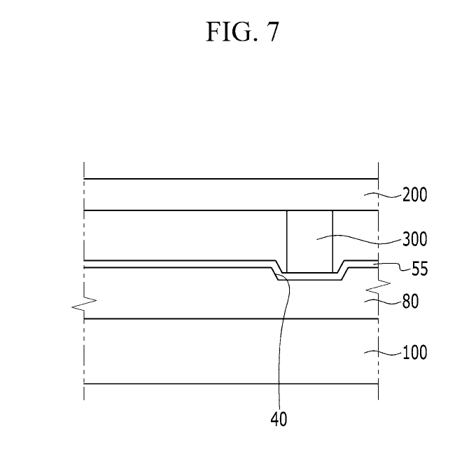

FIG. 5 is a top plan view of a portion A of FIG. 1, FIG. 6A is a cross-sectional view taken along the line VI-VI of FIG. 5, and FIG. 7 is a cross-sectional view taken along the line VII-VII of FIG. 5.

As shown in FIG. 5 to FIG. 7, an insulating layer 80 is formed on the substrate 100. The insulating layer 80 may include one of the gate insulating layer 140, the first interlayer insulating layer 160, and the second interlayer insulating layer 180 of FIG. 4.

An insulating layer 80 includes a plurality of recess portions 40. Each recess portion 40 is longer than a width of the sealing member 300 such that the recess portion 40 transverses the sealing member 300.

A plurality of wires 55 are formed on the insulating layer 80. Each wire transverses the sealing member 300 and is connected to the thin film transistor and the driver of the pixel unit, and may be a signal line to transmit a signal to at least one of the gate line, the data line, and the driving voltage line of the pixel.

The wire 55 includes a portion that overlaps the recess portion 40. The width W1 of the recess portion 40 is wider than the width W2 of the wire 55, and a depth T1 of the recess portion 40 is the same as a thickness T2 of the wire 55 thereby forming a structure in the insulating layer 80 in which the wire 55 is inserted in the recess portion 40. Accordingly, the wire 55 positioned in the recess portion 40 does not protrude on an upper surface of the insulating layer 80 including the recess portion 40.

The depth of the recess portion and the thickness of the wire may be equal to each other, however it may be that, due to a process error, the depth T1 of the recess portion is less than the thickness (T2)*2 of the wire 55.

That is, if it is that the depth T1 of the recess portion is less than the thickness T2′ of the wire (Refer to FIG. 6B), the wire is not completely inserted in the recess portion, but may protrude. However, in such a case a portion of the wire is inserted in the recess portion so that only a portion of the wire protrudes outside of the recess portion, and the size of a step formed along by the wire 55 with the insulating layer 80 is smaller than a step conventionally formed by an entire wire, thereby reducing damage due to the step.

As shown in an example embodiment, the recess portion 40 crossing the sealing member 300 is formed, and the wire 55 does not protrude on or above a top surface of the insulating layer 80 and is positioned within the recess portion 40 such that a step due to a wire is not formed. Accordingly, when an external impact is applied to the sealing member 300 crossing on the wire 55, damage due to the step may be prevented.

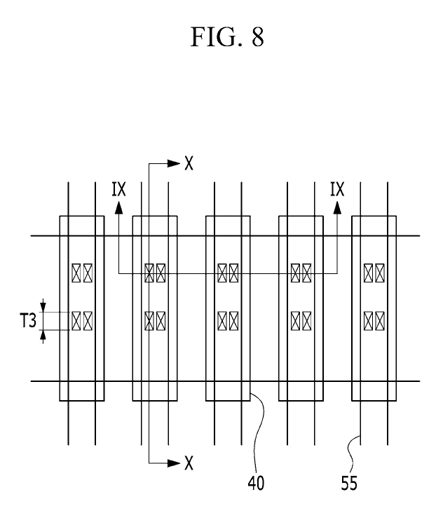

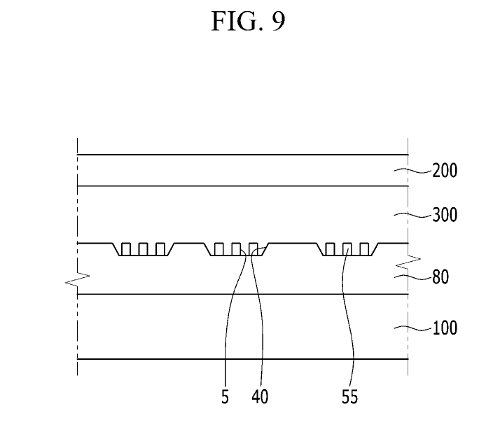

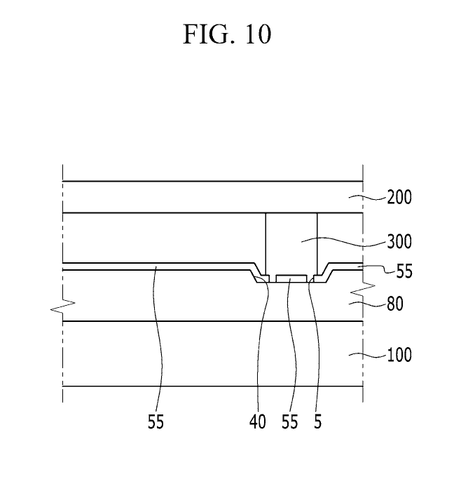

FIG. 8 is a top plan view of a portion A of FIG. 1, FIG. 9 is a cross-sectional view taken along the line IX-IX of FIG. 8, and FIG. 10 is a cross-sectional view taken along the line X-X of FIG. 8.

Most of the layered configuration of FIG. 8 to FIG. 10 is the same as that of FIGS. 5 to 7 such that differences will be described in detail.

The insulating layer 80 having the recess portion 40 is formed on the substrate 100 of FIG. 8 to FIG. 10, the wire 55 overlapping the recess portion 40 is formed on the insulating layer 80, and the sealing member 300 that crosses the recess portion 40 and the wire 55 is formed on the wire 55 within the recess portion 40.

Differently from FIG. 5 to FIG. 7, the wire 55 of FIG. 8 to FIG. 10 includes a plurality of openings 5.

Each opening 5 is positioned on a portion of the wire 55 that is within the recess portion 40, and increases a contact area of the sealing member 300 such that a bending force of the sealing member 300 is increased.

The width T3 of the opening 5 is formed to be less than the thickness of the wire 55 such that protrusions and depressions for increasing the contact area are formed. If the width T3 of the opening 5 is larger than the thickness of the wire 55, the step is formed by the thickness of the wire such that the sealing member 300 due to the step may be easily damaged by external impact. Accordingly, it is preferable that the width T3 of the opening 5 is formed to be smaller than the thickness T2 of the wire such that the step due to the thickness of the wire 55 is not influenced by the sealing member.

In FIG. 8, the opening 5 is disposed to form a quadrangular matrix, however the opening 5 may be randomly disposed with a circular or a polygonal shape according to the width of the wire 55 and the width of the recess portion 40.

According to an example embodiment, a recess portion is formed and a wire crossing the sealing portion is positioned within the recess portion. Thus, a step due to the wire may be reduced such that a reduction of the bonding force of the sealing member due to the step and damage by an external impact may be prevented.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the disclosure, including the appended claims.

What is claimed is:

1. An organic light emitting diode (OLED) display comprising:
a substrate and an encapsulation substrate facing each other;
a sealing member between the substrate and the encapsulation substrate configured to seal the substrate and the encapsulation substrate;
a plurality of pixels on the substrate sealed by the sealing member;
a driver on the substrate and electrically connected to at least one of the plurality of pixels by a wire; and
an insulating layer on the substrate and having a recess portion formed at a region corresponding to a position of the sealing member,
wherein the wire is positioned within the recess portion.

2. The OLED display of claim 1, wherein
a depth of the recess portion is the same as a thickness of the wire.

3. The OLED display of claim 2, wherein
the wire has a plurality of openings.

4. The OLED display of claim 3, wherein
a width of at least one of the plurality of openings in a direction along a length of the wire is smaller than a thickness of the wire.

5. The OLED display of claim 1, wherein
the pixel includes a thin film transistor formed on the substrate, and an organic light emitting element connected to the thin film transistor.

6. The OLED display of claim 5, wherein
the organic light emitting element includes a first electrode, an organic emission layer formed on the first electrode, and a second electrode formed on the organic emission layer, and
the first electrode is connected to a drain electrode of the thin film transistor through a contact hole formed in an interlayer insulating layer.

7. The OLED display of claim 6, wherein
the insulating layer is the interlayer insulating layer.

8. The OLED display of claim 7, wherein
the insulating layer further includes a gate insulating layer positioned between a gate electrode and a semiconductor of the thin film transistor.

9. The OLED display of claim 1, wherein
the recess portion and the wire cross the sealing member.

10. The OLED display of claim 1, wherein the recess portion is positioned in a top surface of the insulating layer opposite a surface of the insulating layer facing the substrate.

11. The OLED display of claim 10, wherein the sealing portion contacts the top surface of the insulating layer and the wire.

12. The OLED display of claim 1, wherein a depth of the recess portion is less than a thickness of the wire.

13. The OLED display of claim 3, wherein the sealing member is positioned in the openings.
